(19) United States
(12) Patent Application Publication
(10) Pub. No.: US 2014/0141624 A1
(43) Pub. Date: May 22, 2014

(54) METHOD OF MANUFACTURING TUNNEL BARRIER LAYER OR GATE INSULATOR FILM AND APPARATUS FOR MANUFACTURING TUNNEL BARRIER LAYER OR GATE INSULATOR FILM

(71) Applicant: IZA CORPORATION, Tokyo (JP)

(72) Inventor: Noel Abarra, Fuchu-shi (JP)

(73) Assignee: IZA CORPORATION, Tokyo (JP)

(21) Appl. No.: 14/081,370

(22) Filed: Nov. 15, 2013

(30) Foreign Application Priority Data
Nov. 16, 2012 (JP) 2012-252400
Sep. 12, 2013 (JP) 2013-189742

(51) Int. Cl. H01L 21/02

(52) U.S. Cl. CPC H01L 21/02266
USPC 438/778; 204/298.02; 204/298.11

(57) ABSTRACT

It is an object of the present invention to provide a method of and an apparatus for manufacturing a tunnel barrier layer or a gate insulator film with good film quality and film thickness uniformity. The present invention is characterized in that, a shield is configured to shield a region of a substrate to which an erosion region of a target is projected along a normal from a surface of the target and sputtered particles are configured to deposit on the substrate linearly moved when passing through an opening formed in the shield.

### BACKGROUND OF THE INVENTION

1. Field of the Invention

The present invention relates to a method of manufacturing a tunnel barrier layer or a gate insulator film and an apparatus for manufacturing a tunnel barrier layer or a gate insulator film

2. Background Art

Hard disk drives (HDDs) currently manufactured use magnetic tunnel junction (MTJ) devices utilizing magnesium oxide (MgO) tunnel barriers as the reading transducer thereof For example, publication of Japan Patent Application JP2009-151891A describes a method of performing RF sputtering for an MgO target as a method of manufacturing an MgO tunnel barrier.

The aforementioned publication describes a method of manufacturing a magneto-resistance effect device. The method has 3 steps: lower magnetic layer deposition, dielectric layer (MgO) deposition, and upper magnetic layer deposition, which are made by sputtering with a wide distribution of oblique incidence angles. The method for sputtering the MgO dielectric layer is by oblique RF deposition on a rotating substrate from targets offset from a normal axis from the center of the substrate.

The tunnel barrier layer is required to simultaneously have a high MR ratio and a low RA value (<1Ωμm²). The magneto-resistance (MR) ratio herein refers to a resistance variation ratio of a tunnel magneto-resistance (TMR) device, which greatly varies with the relative orientation of magnetization of the magnetization layers on either side of the MgO dielectric. The MR ratio is a measure of the resistance difference between when the magnetization directions are parallel and anti-parallel. Furthermore, the areal resistance (RA) is a resistance value normalized by a unit area (1 μm²) of a TMR device. As device dimensions are being reduced to increase HDD areal densities, the RA needs to be reduced to control the device resistance. RA reduction has been mainly achieved by reduction of the tunneling barrier layer thickness. With this trend, tunnel barrier layers with good film quality at the molecular layer level are more difficult to form with such disclosed method as described in the aforementioned publication. Embodiments of the present invention provide an apparatus that avoid the problems with current deposition systems in forming dielectric films of high quality for tunnel barriers as well as thin gate insulators. During MgO sputtering, negative oxygen ions are formed on the target surface. These ions are accelerated by the cathode electric field in the direction normal to the target surface. At low sputtering pressures, the negative ion energies can be significant and if the substrate is on the ion bombardment path, the ions adversely affect the crystallographic properties and morphology of the dielectric film being formed or even of the ferromagnetic layer that the film is being formed on. The adverse effect of ion bombardment may be reduced by increasing the working gas pressure during sputtering. However, this also reduces the kinetic energy of the sputtered particles that are necessary for dense smooth films

Moreover, as targets are offset with current deposition methods, the incidence angle is oblique and not uniform throughout a wafer. For a portion farthest away from the target, the incidence angle may be >50° from the substrate normal. This is consistent with the observed MR ratio and especially RA varying with radius even for a film of uniform thickness; tunneling properties are non-uniform between the center part of the substrate and the outer edge part of the substrate.

In view of the above, it is an object of the present invention to provide a method of manufacturing a tunnel barrier layer or a gate insulator film with good film quality and uniformity and an apparatus for manufacturing a tunnel barrier layer or a gate insulator film

### SUMMARY OF THE INVENTION

A method of manufacturing a tunnel barrier layer or a gate insulator film according to the present invention is a manufacturing method configured to form the tunnel barrier layer or the gate insulator film on a surface of a substrate by means of sputtering of a target. The method is characterized in that, while a shield is configured to shield a region of the substrate to which an erosion region of the target is projected along a normal from a surface of the target and further shield a region that an incidence angle formed by a normal from the surface of the substrate and an incidence direction of each of sputtered particles produced from a center of the target is greater than 45 degrees, the sputtered particles are configured to deposit on the substrate linearly moved when the sputtered particles pass through an opening formed in the shield.

An apparatus for manufacturing a tunnel barrier layer or a gate insulator film according to the present invention is a manufacturing apparatus configured to form the tunnel barrier layer or the gate insulator film on a surface of a substrate by means of sputtering of a target. The manufacturing apparatus is characterized in including a shield and a substrate holding part. The shield is configured to shield a region of the substrate to which an erosion region of the target is projected along a normal from a surface of the target and further shield a region that an incidence angle formed by an incidence direction of each of sputtered particles produced from a center of the target and a normal from the surface of the substrate is greater than 45 degrees. The substrate holding part is configured to linearly move the substrate along a feeding path. Further, the manufacturing apparatus is characterized in that the sputtered particles are configured to deposit on the surface of the substrate when the sputtered particles pass through an opening formed in the shield. Advantageous Effects of Invention

According to the present invention, the substrate is shielded from negative oxygen ions accelerated by a cathode electric field. High energy ion bombardment that deteriorates the quality of either a tunnel barrier layer or a gate insulator film is avoided. Moreover, the process space is enlarged as lower pressure processes which promote dense smooth high quality sputtered films are accessible without the adverse effect of ion bombardment.

The trajectory of sputtered particles impinging on the substrate may also be controlled by judicious positioning of the slit opening as well as a choice of slit width. Near normal incidence is also possible which is more advantageous for forming dense films than oblique incidence sputtering. There is more uniformity in the distribution of incidence angles as a similar flux of particles lands on segments of the substrate as the substrate is scanned proximate to the opening. The slit opening width may be slightly modified to obtain thickness uniformity along a direction perpendicular to the scanning direction. Therefore, both film thickness and incidence distribution uniformity are achieved.

### BRIEF DESCRIPTION OF THE DRAWINGS

Referring now to the attached drawings which form a part of this original disclosure:

FIG. 1A and FIG. 1B are schematic diagrams for showing a positional relation between a target and a substrate in a well-known apparatus for manufacturing either a tunnel barrier layer or a gate insulator film, and includes FIG. 1A as a vertical view of the positional relation and FIG. 1B as a plan view of the substrate;

FIG. 2 is a cross-sectional view of a construction of a reading part of a magnetic head of a hard disk drive;

FIG. 3 is a vertical cross-sectional view of an entire construction of an apparatus for manufacturing a tunnel barrier layer or a gate insulator film according to a first exemplary embodiment of the present invention;

FIG. 4 is a schematic plan view of a modification of a shield of the apparatus for manufacturing a tunnel barrier layer or a gate insulator film according to the first exemplary embodiment of the present invention;

FIG. 5 is a vertical cross-sectional view of an entire construction of an apparatus for manufacturing a tunnel barrier layer or a gate insulator film according to a second exemplary embodiment of the present invention;

FIG. 6A and FIG. 6B are schematic perspective views of modifications of a shield of the apparatus for manufacturing a tunnel barrier layer or a gate insulator film according to the second exemplary embodiment of the present invention, and includes FIG. 6A showing a modification (1) and FIG. 6B showing a modification (2); and

FIG. 7 is a vertical cross-sectional view of an entire construction of an apparatus for manufacturing a tunnel barrier layer or a gate insulator film according to a third exemplary embodiment of the present invention.

### DETAILED DESCRIPTION OF THE EMBODIMENTS

With reference to the attached drawings, exemplary embodiments of the present invention will be hereinafter explained in detail.

### 1. Overview of Present Invention

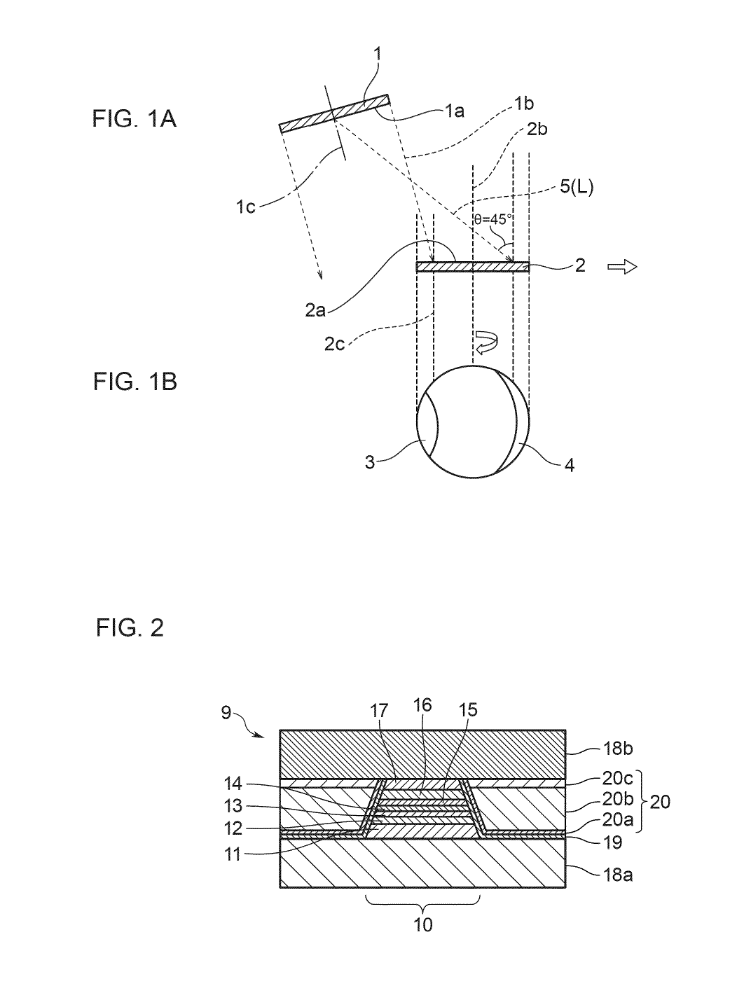

FIG. 1A and FIG. 1B are schematic diagrams showing an exemplary positional relation between a target 1 and a substrate 2 in a well-known apparatus for manufacturing a dielectric film (e.g., a tunnel barrier layer or a gate insulator film) The substrate 2 is held such that the surface thereof (substrate surface 2a) is horizontally arranged. The target 1 is held while being obliquely tilted with respect to the substrate surface 2a. During film deposition, the substrate 2 is configured to be rotated about an axis 2b for forming a uniform thin film on the substrate surface 2a.

As described above, oxygen ions, contained in the target 1 or the atmosphere, are accelerated perpendicularly to a target surface 1a by a cathode electric field to be generated by high frequency power applied to the target 1. The oxygen ions are negatively charged. The accelerated oxygen ions collide with a region 3 of the substrate 2, i.e., a region to which the target 1 is projected along a normal 1b from the target surface 1a. The film quality of a dielectric film in the region 3 is thereby deteriorated.

A region 4 is a region that an angle θ, formed by a normal 2c from the substrate surface 2a and an incidence direction 5 of each of sputtered particles produced from the center of the target 1, is greater than 45 degrees (note the angle θ will be hereinafter referred to as “an incidence angle”). In the region 4, the sputtered particles cannot deposit on the substrate in a roughly perpendicular direction. In other words, the (001) orientation of a deposited film is deteriorated in the region 4. The film quality of the dielectric film deposited in the region 4 is thereby deteriorated.

Film deposition is performed while the substrate 2 is rotated. Therefore, uniformity in film thickness can be achieved in the rotational direction of the substrate 2. However, uniformity in tunneling properties cannot be easily achieved in the radial direction of the substrate 2. Hence, limitation is imposed on enhancement in uniformity of a dielectric film to be formed.

By contrast, the present invention is configured to shield deposition of the sputtered particles on the regions 3 and 4 in order to prevent deterioration in film quality of a dielectric film to be deposited on the substrate surface 2a. Moreover, the present invention is configured to move the substrate 2 in a linear direction (an arrow direction in the drawing) and accordingly cause the substrate surface 2a to entirely pass through a position away from a given position on the target surface la, for instance, at a distance of L in order to uniformly form a dielectric film with good film quality on the entire substrate surface 2a.

### 2. Reading Part of Magnetic Head

Next, a construction of a reading part of a magnetic head of a hard disk drive (HDD) will be explained as an exemplary application of a tunnel barrier layer to be formed by an apparatus for manufacturing a tunnel barrier layer or a gate insulator film (hereinafter simply referred to as “a manufacturing apparatus”) according to the present invention.

As shown in FIG. 2, a reading part 9 is composed of a magneto-resistance sensor 10 and a hard bias 20. The magneto-resistance sensor 10 is sandwiched by a lower shield 18a and an upper shield 18b, both of which are normally made of permalloy. The hard bias 20 includes a seed layer 20a, a ferromagnetic layer 20b and a cap layer 20c. The ferromagnetic layer 20b has high saturation coercive force and provides the magneto-resistance sensor 10 with a transverse field.

An insulator layer 19 electrically separates the magneto-resistance sensor 10 from the hard bias 20. The magneto-resistance sensor 10 normally includes an antiferromagnetic layer 11, a magnetic fixed layer 12, a spacer layer 13, a magnetic reference layer 14, a tunnel barrier layer 15, a magnetization free layer 16 and a cap layer 17. It should be noted that the tunnel barrier layer 15 is an extremely thin layer that is made of metal oxide (e.g., MgO) and has a film thickness of 5 nm or less, and more preferably, a film thickness of 3 nm or less.

The magnetic moment of the magnetic reference layer 14 is antiferromagnetically coupled to that of the magnetic fixed layer 12 through the spacer layer 13. The magnetic moment of the magnetic fixed layer 12 is fixed by the antiferromagnetic layer 11.

In some designs, the antiferromagnetic layer 11 is not disposed, and the magnetic moment of the magnetic fixed layer 12 is aligned perpendicularly to an air bearing surface (ABS) by means of anisotropic stress. The magnetic moment of the magnetic fixed layer 12 and that of the magnetic reference layer 14 are substantially perpendicular to the ABS, whereas the magnetic moment of the magnetization free layer 16 is transversely biased by means of the magnetic field from the ferromagnetic layer 20b.

Detection current flows through the magneto-resistance sensor 10 via the upper shield 18b and the lower shield 18a. The magnetic moment of the magnetization free layer 16 is rotated perpendicularly to the ABS by means of the magnetic field from bits on a magnetic disk medium. Consequently, variation in resistance of the magneto-resistance sensor 10 is caused, and is detected as variation in voltage.

The upper and lower shields 18b and 18a are generally formed by means of electric plating. On the other hand, the magneto-resistance sensor 10 is formed in a manufacturing apparatus in which multiple targets are installed. It should be noted that the tunnel barrier layer 15 is formed in another manufacturing apparatus in which multiple targets are installed and which is prepared exclusively for forming the tunnel barrier layer 15.

### 3. First Exemplary Embodiment

### (3-1) Entire Construction

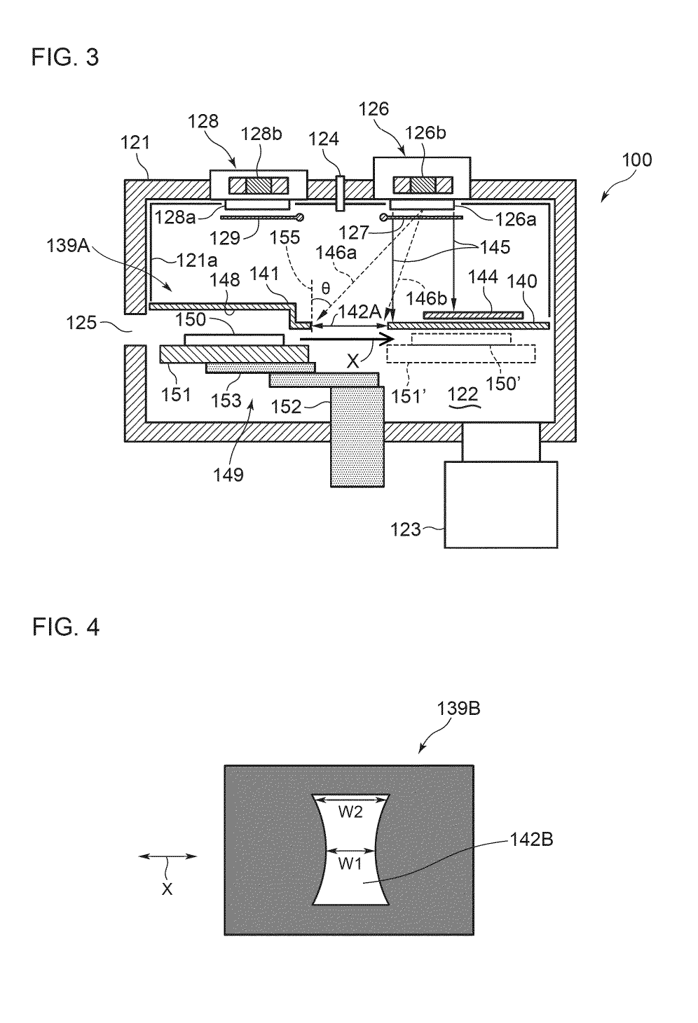

Next, explanation will be made for a manufacturing apparatus for forming the tunnel barrier layer according to a first exemplary embodiment of the present invention. As shown in FIG. 3, the present manufacturing apparatus 100 includes a vacuum chamber 121. Process gas, required for film deposition by means of sputtering, is supplied to the vacuum chamber 121 from the outside through a process gas inlet port 124. The vacuum chamber 121 is provided with a vacuum pump 123 for discharging the aforementioned process gas and impurity gas flowing therein from the external space. To form a tunnel barrier layer, the interior of the vacuum chamber 121 is preferably kept at a pressure of 8.0×10⁻⁹ Torr or less through the discharge of the vacuum pump 123. Further, the vacuum chamber 121 has a substrate installation port 125 for carrying a substrate 150 in and out of the interior of the chamber 121 (vacuum chamber interior 122). The inner surface of the vacuum chamber 121 may be coated with a coating material 121a. With the coating material 121a disposed on the inner peripheral surface of the vacuum chamber 121, the manufacturing apparatus 100 can prevent the sputtered particles from attaching to the inner surface of the vacuum chamber 121.

A first cathode part 126, a second cathode part 128 and a substrate holding part 149 are disposed in the vacuum chamber interior 122. The first cathode part 126 includes a first target 126a as a target and a magnet unit 126b disposed on the back-surface side of the first target 126a. A dielectric material (e.g., an oxide target) is preferably used as the first target 126a. More specifically, magnesium oxide is applied as the first target 126a. The second cathode part 128 includes a second target 128a and a magnet unit 128b disposed on the back-surface side of the second target 128a. The second target 128a is made of a getter material (e.g., Ta or Ti).

The first and second targets 126a and 128a are disposed such that the surfaces thereof can be roughly in parallel to the surface of the substrate 150 held by the substrate holding part 149. Furthermore, electric power required for sputtering is applied to the first target 126a and the second target 128a, respectively, from a power supply line (not shown in the drawing). Although not shown in the drawing, the power supply line is connected to a high frequency power source and a direct-current power source.

The first target 126a is provided with a first target shutter 127, whereas the second target 128a is provided with a second target shutter 129. The first target shutter 127 and the second target shutter 129 prevent the first target 126a and the second target 128a from being contaminated with each other.

Specifically, the manufacturing apparatus 100 is configured to open the first target shutter 127, and simultaneously, close the second target shutter 129, while sputtering is performed using the first cathode part 126. Thus, the manufacturing apparatus 100 prevents the first cathode part 126 from contaminating the second target 128a by closing the second target shutter 129.

Likewise, the manufacturing apparatus 100 is configured to open the second target shutter 129, and simultaneously, close the first target shutter 127, while sputtering is performed using the second cathode part 128. Thus, the manufacturing apparatus 100 prevents the second cathode part 128 from contaminating the first target 126a by closing the first target shutter 127.

The substrate holding part 149 includes a holder mount 151 and a robot 152. The holder mount 151 holds the substrate 150 in a roughly horizontal position. The robot 152 is configured to linearly move the holder mount 151 in a direction along a feeding path (an X direction in the drawing). The robot 152 is provided with an arm 153. The holder mount 151 is joined to the arm 153. In this case, the X direction is arranged in parallel to the surface of the substrate 150. It should be noted that from the perspective of film thickness uniformity, the moving of the substrate 150 is desirably a uniform linear motion with constant velocity. Moreover, the feed speed of the substrate 150 is preferably set to be 0.6 mm/sec or less in consideration of a low sputter film deposition rate (of roughly 0.005 nm/s) of a target using magnesium oxide.

The manufacturing apparatus 100 according to the present exemplary embodiment has a characteristic construction of the present invention in addition to the aforementioned basic construction. The characteristic construction will be hereinafter explained. The manufacturing apparatus 100 is provided with a shield 139A. The shield 139A is disposed between the first and second targets 126a and 128a and the substrate 150 held by the holder mount 151.

The shield 139A includes a first shield 140 and a second shield 141. The first and second shields 140 and 141 are disposed in parallel to the surface of the holder mount 151. Each of the first and second shields 140 and 141 is formed by a plate-shaped member. The first and second shields 140 and 141 are disposed at a predetermined interval, while one side of the first shield 140 and that of the second shield 141 are opposed to each other. An opening 142A is formed in a region interposed between the opposed sides of the first and second shields 140 and 141. In the present exemplary embodiment, the opening 142A is formed in a rectangular shape and is disposed such that the long sides thereof are arranged perpendicularly to the plane of the drawing.

The first shield 140 is disposed so as to be capable of shielding the sputtered particles produced from an erosion region of the surface of the first target 126a in the normal direction. It should be noted that the erosion region herein refers to a region of the target surface from which the sputtered particles are produced, and refers to all or part of the target surface.

In the present exemplary embodiment, the first shield 140 is disposed immediately below the first cathode part 126 in order to shield a region of the substrate 150 held by the holder mount 151, i.e., a region to which the first target 126a is projected along a normal 145 from the surface of the first target 126a. More specifically, the first shield 140 shields a region enclosed by normals from the surface of the first target 126a that pass through the outer edge of an erosion region on the first target 126a regardless of the location of erosion caused on the first target 126a.

The second shield 141 is disposed for shielding a region that an angle formed by an incidence direction 146a of each of the sputtered particles produced from the center of the first target 126a and a normal 155 from the surface of the substrate 150 held by the holder mount 151, that is, the incidence angle θ of each of the sputtered particles produced from the center of the first target 126a, is greater than 45 degrees. With the construction, the second shield 141 shields most of such sputtered particles that the incidence angles 0 thereof to the surface of the substrate 150 are large.

Here, the incidence angle θ refers to the angle formed by the incidence direction 146a of each of the sputtered particles produced by the first target 126a and the normal 155 from the surface of the substrate 150. Furthermore, in FIG. 3, the incidence angle is defined as positive where the incidence direction of each sputtered particle is tilted clockwise with respect to the normal from the surface of the first target 126a. On the other hand, the incidence angle is defined as negative where the incidence direction of each sputtered particle is tilted counterclockwise with respect to the normal from the surface of the first target 126a. Therefore, where the incidence angle θ of each of the sputtered particles produced from the center of the first target 126a is greater than 45 degrees, this indicates that the absolute value of the positive/negative incidence angle θ of each of the sputtered particles produced from the center of the first target 126a is greater than 45 (degrees).

The second shield 141 has a step 148 for enabling the holder mount 151 to be moved in the up-and-down direction. The step 148 is continued to the substrate installation port 125. The manufacturing apparatus 100 can carry the substrate 150 onto the holder mount 151 through the substrate installation port 125 and carry the substrate 150 mounted onto the holder mount 151 out through the substrate installation port 125 by elevating the holder mount 151 at the step 148.

The shield 139A includes a shutter 144 for closing the opening 142A. The shutter 144 is disposed on the first shield 140 while being disposed in parallel to the surface of the first shield 140. The shutter 144 is configured to be moved along the feeding path. The shutter 144 is configured to proceed onto the opening 142A for adjusting the feeding-path directional width of the opening 142A. In other words, the shutter 144 can partially or completely close the opening 142A. On the other hand, the shutter 144 is configured to be retracted onto the first shield 140 whereby the opening 142A can be completely opened as shown in the drawing.

### (3-2) Actions and Effects

Next, explanation will be made for actions and effects of the manufacturing apparatus 100 with the aforementioned construction. To form the tunnel barrier layer 15 on the magnetic reference layer 14, the substrate 150 (FIG. 2) with the magnetic reference layer 14 formed thereon is carried onto the holder mount 151 through the substrate installation port 125 shown in FIG. 3.

The manufacturing apparatus 100 is configured to perform sputtering of a getter material by applying high frequency power to the second target 128a, while the shutter 144 and the first target shutter 127 are closed whereas the second target shutter 129 is opened. The getter material, sputtered from the second target 128a, is thereby attached to the inner surface of the vacuum chamber 121. The manufacturing apparatus 100 is configured to close the second target shutter 129 and turn off the high frequency power applied to the second target 128a after performing sputtering for a predetermined period of time.

Next, the manufacturing apparatus 100 is configured to perform sputtering by applying high frequency power to the first target 126a, while the shutter 144 and the first target shutter 127 are opened whereas the second target shutter 129 is closed. Simultaneously, the substrate holding part 149 is configured to linearly move the substrate 150. The substrate 150 is thereby caused to pass immediately below the opening 142A. Sputtered particles, produced from the surface of the first target 126a through the sputtering, pass through the opening 142A formed in the shield 139A and deposit on the surface of the substrate 150.

It should be noted that the following regions are shielded: a region on the substrate 150 held by the holder mount 151, i.e., a region to which an erosion region of the first target 126a is projected along the normal 145 from the surface of the first target 126a; and a region that the incidence angle θ of each of the sputtered particles produced from the center of the first target 126a is greater than 45 degrees. Therefore, most of the sputtered particles passing through the opening 142A are particles with specific orientations that the incidence angle θ is 45 degrees or less and is not 0 degrees. The manufacturing apparatus 100 is configured to form the tunnel barrier layer 15 on the surface of the substrate 150 with most of the sputtered particles with specific orientations that have passed through the opening 142A as described above.

Oxygen ions, contained in the first target 126a and the vacuum chamber interior 122, are accelerated along the normal 145 from the surface of the first target 126a by means of the cathode electric field generated by the high frequency power applied to the first target 126a. The accelerated oxygen ions collide with the first shield 140.

Thus, the manufacturing apparatus 100 can prevent the oxygen ions accelerated by the cathode electric field from colliding with the surface of the substrate 150 by shielding the accelerated oxygen ions with the first shield 140. Therefore, the manufacturing apparatus 100 can prevent deterioration in film quality of the tunnel barrier layer 15 attributed to collision of the accelerated oxygen ions.

Moreover, amongst the sputtered particles produced from the surface of the first target 126a through the sputtering, most of such sputtered particles with the incidence angle θ of greater than 45 degrees collide with the second shield 141. Thus, the manufacturing apparatus 100 shields most of such sputtered particles with the incidence angle θ of greater than 45 degrees by the second shield 141. The manufacturing apparatus 100 can thereby suppress deposition of such sputtered particles with the incidence angle θ of greater than 45 degrees on the surface of the substrate 150. Consequently, the manufacturing apparatus 100 can prevent deterioration in film quality of the tunnel barrier layer 15 attributed to the condition that such sputtered particles with the incidence angle θ of greater than 45 degrees deposit on the substrate 150 and thereby the sputtered particles cannot deposit on the substrate 150 in a roughly perpendicular direction.

The substrate holding part 149 is configured to linearly move the substrate 159 during film deposition. In other words, the substrate holding part 149 is configured to cause the robot 152 to extend and contract the arm 153 for moving the substrate 150 and the holder mount 151 respectively to the positions indicated by reference numerals 150′ and 151′ in the X direction in the drawing. The entire surface of the substrate 150 is thereby caused to pass immediately below the opening 142A in the X direction. The substrate holding part 149 is again configured to cause the robot 152 to extend and contract the arm 153 for moving the substrate 150′ and the holder mount 151′ respectively to the positions indicated by the reference numerals 150 and 151 in a direction opposite to the X direction in the drawing. The entire surface of the substrate 150 is thereby caused to pass immediately below the opening 142A in the direction opposite to the X direction.

Thus, the manufacturing apparatus 100 performs film deposition while moving the substrate 150 in the X direction and again moving the substrate 150 in the direction opposite to the X direction. The entire surface of the substrate 150 is thereby caused to pass the position located away from a given position on the surface of the first target 126a at a constant distance. Hence, the manufacturing apparatus 100 can uniformly form the tunnel barrier layer 15 with good film quality on the entire surface of the substrate 150.

The manufacturing apparatus 100 according to the present exemplary embodiment is designed to be provided with the coating material 121a and is configured to cause the second cathode part 128 to coat the inner surface of the vacuum chamber 121 with the getter material. Accordingly, gases such as water vapor can be absorbed by the coating material 121a and the getter material. Hence, the manufacturing apparatus 100 can further enhance the film quality of the tunnel barrier layer 15.

The shape of the erosion region on the first target 126a varies over the film deposition time. Accordingly, the directions of the sputtered particles produced from the surface of the first target 126a also vary. Therefore, the directions of accelerating oxygen ions are slightly deviated from the direction arranged along the normal from the surface of the first target 126a. It is possible to grasp deviation of oxygen ions from the direction arranged along the normal from the surface of the first target 126a by checking whether or not the film quality of the tunnel barrier layer 15 formed on the substrate 150 is deteriorated by oxygen ions.

To cope with the above, the manufacturing apparatus 100 according to the present exemplary embodiment is configured to cause the shutter 144 to close a part of the opening 142A. It is thereby possible to shield accelerated oxygen ions deviated from the direction arranged along the normal from the surface of the first target 126a. Thus, the manufacturing apparatus 100 can more reliably shield oxygen ions, and accordingly, can more reliably form the tunnel barrier layer 15 with good film quality.

Limitations are not particularly imposed on the first and second targets 126a and 128a. However, the first and second targets 126a and 128a are preferably formed in rectangular shapes and are disposed such that the long sides thereof are arranged roughly perpendicularly to the plane of the drawing in order to achieve uniform film deposition on the surface of the substrate 150 while the substrate 150 is linearly moved.

The aforementioned exemplary embodiment has explained the example that the opening 142A formed in the shield 139A has a rectangular shape. However, in the present invention, the construction of the opening is not limited to the above. For example, a shield 139B shown in FIG. 4 is made of a single plate-shaped member, and has an opening 142B bored therethrough in the thickness direction. The opening 142B may be formed such that a length (width) W1 in the vicinity of the center part thereof can be shorter than a length (width) W2 in the end thereof The opening 142B thus bored is disposed such that the center thereof can be aligned with that of the first target 126a. Further, the substrate 150 is linearly moved along the X direction in the drawing. Therefore, the film deposition rate of the center part of the first target 126a and that of the outer peripheral part of the first target 126a can be equally set by thus reducing the length W1 of the opening 142A in the vicinity of the center of the first target 126a. Consequently, with the application of the shield 139B according to the modification, the manufacturing apparatus 100 can more uniformly form the tunnel barrier layer 15.

### 4. Second Exemplary Embodiment

### (4-1) Entire Construction

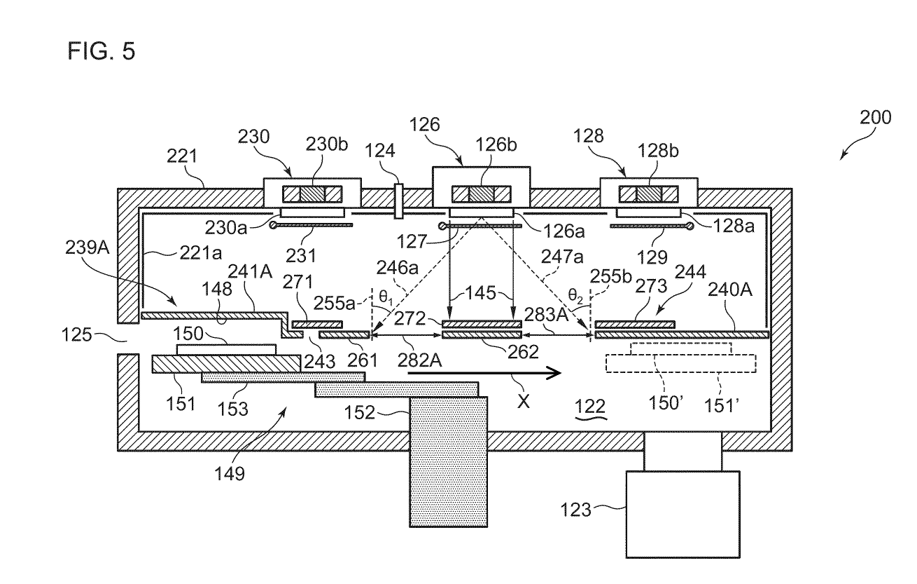

Next, with reference to FIG. 5, explanation will be made for a manufacturing apparatus according to a second exemplary embodiment. A manufacturing apparatus 200 according to the present exemplary embodiment is different from the manufacturing apparatus 100 according to the first exemplary embodiment in that the manufacturing apparatus 200 includes a third cathode part. In the following description, explanation will be made for the third cathode part and constructional changes in accordance with the installation of the third cathode part, whereas explanation for components provided similarly to those in the first exemplary embodiment will be omitted. In the drawing, the same reference numerals are assigned to the same components as those used in the first exemplary embodiment.

As shown in the drawing, the manufacturing apparatus 200 according to the present exemplary embodiment includes a third cathode part 230 in addition to the first cathode part 126 and the second cathode part 128. The third cathode part 230 includes a third target 230a and a magnet unit 230b disposed on the back-surface side of the third target 230a. When the first target 126a is made of magnesium oxide (MgO), the third target 230a is preferably made of magnesium (Mg) in accordance with the first target 126a.

The third target 230a is disposed roughly in parallel to the surface of the substrate 150 held by the holder mount 151. Furthermore, electric power required for sputtering is applied to the third target 230a from a power supply line (not shown in the drawing). Although not shown in the drawing, the power supply line is connected to a high frequency power source and a direct-current power source.

The third target 230a is provided with a third target shutter 231. The third target shutter 231 prevents the third target 230a from being contaminated by the first target 126a and the second target 128a.

In the manufacturing apparatus 200, the first cathode part 126 is disposed in the center. The third cathode part 230 is disposed on the substrate installation port 125 side, whereas the second cathode part 128 is disposed on the opposite side of the substrate installation port 125.

The manufacturing apparatus 200 is provided with a shield 239A. The shield 239A is disposed between the first, second and third targets 126a, 128a and 230a and the substrate 150 held by the holder mount 151. The shield 239A includes a first shield 240A and a second shield 241A. A first mask 261 and a second mask 262 are disposed in a region interposed between one side of the first shield 240A and that of the second shield 241A, i.e., the opposed sides of the first and second shields 240A and 241A.

Each of the first and second masks 261 and 262 is formed by a plate-shaped member. The first and second masks 261 and 262 are disposed in parallel to the surface of the substrate 150. The first and second masks 261 and 262 are disposed at a predetermined interval, while one side of the first mask 261 and that of the second mask 262 are opposed to each other.

A first opening 282A is formed in a region interposed between the opposed sides of the first and second masks 261 and 262. On the other hand, a second opening 283A is formed in a region interposed between the opposed sides of the second mask 262 and the first shield 240A. Thus, the first opening 282A is formed on one side of the second mask 262, whereas the second opening 283A is formed on the other side of the second mask 262, i.e., the side separated away from the first opening 282A.

A third opening 243 is formed in a region interposed between the opposed sides of the first mask 261 and the second shield 241A. The third opening 243 is formed immediately below the third target 230a.

The second mask 262 is disposed immediately below the first cathode part 126 in order to shield a region of the substrate 150 held by the holder mount 151, i.e., a region to which an erosion region of the first target 126a is projected along the normal 145 from the surface of the first target 126a. More specifically, the second mask 262 shields the region enclosed by normals from the outer edge of the erosion region of the first target 126a regardless of the location of erosion caused on the first target 126a.

The first shield 240A and the first mask 261 are disposed for shielding regions that angles formed by incidence directions 246a and 247a of the sputtered particles produced from the center of the first target 126a and normals 255a and 255b from the surface of the substrate 150 held by the holder mount 151, i.e., the incidence angles θ₁ and θ₂ are greater than 45 degrees. Thus, the first shield 240A and the first mask 261 shield most of such sputtered particles with the incidence angles θ₁ and θ₂ of greater than 45 degrees.

The shield 239A includes a shutter 244 for closing the first opening 282A, the second opening 283A and the third opening 243, respectively. The shutter 244 is composed of a first shutter 271, a second shutter 272 and a third shutter 273. The first shutter 271 is disposed so as to be capable of closing the third opening 243. The second shutter 272 is disposed so as to be capable of closing the first opening 282A. The third shutter 273 is disposed so as to be capable of closing the second opening 283A. The first shutter 271, the second shutter 272 and the third shutter 273 are respectively disposed so as to be moved on and in parallel to the first mask 261, the second mask 262 and the first shield 240A along the feeding path. The first shutter 271, the second shutter 272 and the third shutter 273 are configured to adjust the feeding-path directional width of the third opening 243, that of the first opening 282A and that of the second opening 283A, respectively. In other words, the first shutter 271, the second shutter 272 and the third shutter 273 can completely open, and also, partially or completely close the third opening 243, the first opening 282A and the second opening 283A, respectively on an independent basis.

### (4-2) Actions and Effects

Next, explanation will be made for actions and effects of the manufacturing apparatus 200 with the aforementioned construction. To form the tunnel barrier layer 15 on the magnetic reference layer 14, the substrate 150 (FIG. 2) with the magnetic reference layer 14 formed thereon is carried onto the holder mount 151 through the substrate installation port 125 shown in FIG. 5.

The manufacturing apparatus 200 is configured to perform sputtering of a getter material by applying high frequency power to the second target 128a, while the first shutter 271, the second shutter 272, the third shutter 273, the first target shutter 127 and the third target shutter 231 are closed whereas the second target shutter 129 is opened.

Next, the manufacturing apparatus 200 is configured to perform sputtering by applying high frequency power to the third target 230a, while the second target shutter 129 is closed whereas the third target shutter 231 and the first shutter 271 are opened. Simultaneously, the substrate holding part 149 is configured to linearly move the substrate 150. The substrate 150 is thereby caused to pass immediately below the third opening 243.

Sputtered particles, produced from the surface of the third target 230a through the sputtering, pass through the third opening 243 and deposit on the surface of the substrate 150. Thus, an Mg film is formed on the surface of the substrate 150.

Next, the manufacturing apparatus 200 is configured to perform sputtering by applying high frequency power to the first target 126a, while the third target shutter 231 and the first shutter 271 are closed whereas the first target shutter 127, the second shutter 272 and the third shutter 273 are opened. Simultaneously, the substrate holding part 149 is configured to linearly move the substrate 150. The substrate 150 is thereby caused to pass immediately below the first opening 282A and the second opening 283A.

Sputtered particles, produced from the surface of the first target 126a through the sputtering, pass through the first opening 282A and the second opening 283A, and deposit on the surface of the substrate 150. Thus, the manufacturing apparatus 200 forms an MgO film on the Mg film that has been already formed on the surface of the substrate 150. Actually, the Mg film and the MgO film are integrated and changed into the tunnel barrier layer 15 made of MgO. With use of the third target 230a, an Mg film may be further formed on the tunnel barrier layer 15 made of MgO.

The manufacturing apparatus 200 with the aforementioned construction is configured to shield the region of the substrate 150 held by the holder mount 151, i.e., the region to which an erosion region of the first target 126a is projected along the normal 145 from the surface of the first target 126a, and the regions that the incidence angles θ₁ and θ₂ of the sputtered particles produced from the center of the first target 126a are greater than 45 degrees. Therefore, the manufacturing apparatus 200 can achieve advantageous effects similar to those achieved in the first exemplary embodiment.

In the present exemplary embodiment, the sputtered particles produced from the first target 126a pass through the first and second openings 282A and 283A formed in the shield 239A and deposit on the surface of the substrate 150. Regarding the first and second openings 282A and 283A, the incidence angle θ of each sputtered particle is set to be positive or negative. The incidence angle is herein defined as positive where the incidence direction of each sputtered particle is tilted clockwise with respect to the normal 145 from the surface of the first target 126a in FIG. 5. On the other hand, the incidence angle is defined as negative where the incidence direction of each sputtered particle is tilted counterclockwise with respect to the normal 145 from the surface of the first target 126a in FIG. 5. Based on the definitions, the incidence angle θ₁ of each of the sputtered particles entering through the first opening 282A is set to be positive, whereas the incidence angle θ₂ of each of the sputtered particles entering through the second opening 283A is set to be negative. Hence, the manufacturing apparatus 200 can deposit the sputtered particles with the positive incidence angle θ₁ and those with the negative incidence angle θ₂ on the surface of the substrate 150. It is thereby possible to form the tunnel barrier layer 15 with more uniform film quality and more uniform distribution of film thickness.

In the present exemplary embodiment, the characteristics of the tunnel barrier layer can be enhanced with the construction that the tunnel barrier layer 15 made of MgO is formed on the Mg film Therefore, the manufacturing apparatus 200 can form the tunnel barrier layer 15 with better film quality.

### (4-3) Modifications

(Modification 1)

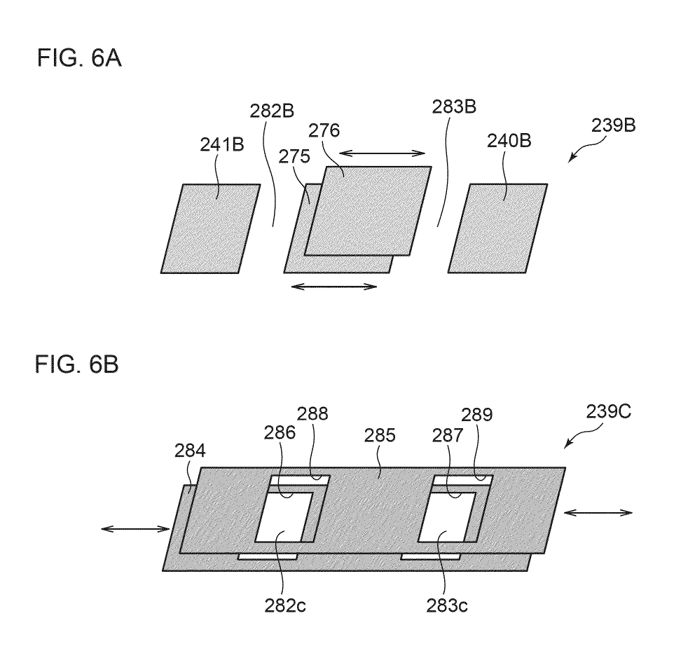

Next, explanation will be made for a modification of the shield according to the second exemplary embodiment. A shield 239B shown in FIG. 6A has a first shield 240B and a second shield 241B. The first shield 240B and the second shield 241B are fixed to a vacuum chamber (not shown in the drawing). A first shutter 275 and a second shutter 276 are disposed in a region interposed between one side of the first shield 240B and that of the second shield 241B, i.e., the opposed sides of the first and second shields 240B and 241B. The first shutter 275 and the second shutter 276 are disposed one above the other, while being movable relatively to and in parallel to each other along the feeding path.

A first opening 282B is formed between the second shield 241B and the first and second shutters 275 and 276. A second opening 283B is formed between the first shield 240B and the first and second shutters 275 and 276. The first and second shutters 275 and 276 are configured to be moved independently from each other. Hence, the first and second shutters 275 and 276 can completely open, and also, partially or completely close the first opening 282B and the second opening 283B, respectively on an independent basis.

Thus, the shield 239B according to the present modification has the first opening 282B and the second opening 283B. Therefore, the shield 239B can achieve advantageous effects similar to those achieved in the second exemplary embodiment.

### (Modification 2)

Next, explanation will be made for another modification of the shield according to the second exemplary embodiment. A shield 239C shown in FIG. 6B includes a first shutter 284 and a second shutter 285. Each of the first and second shutters 284 and 285 is formed by a rectangular plate-shaped member. The first and second shutters 284 and 285 are disposed one above the other, while being movable relatively to and in parallel to each other along the feeding path.

The first shutter 284 has a first through hole 286 and a second through hole 287. The first through hole 286 penetrates through the first shutter 284 in the thickness direction. The second through hole 287 penetrates through the first shutter 284 in the thickness direction, while being disposed away from the first through hole 286 in the longitudinal direction. Each of the first and second through holes 286 and 287 is formed in a rectangular shape.

The second shutter 285 has a third through hole 288 and a fourth through hole 289. The third through hole 288 penetrates through the second shutter 285 in the thickness direction, while being disposed correspondingly to the first through hole 286. The fourth through hole 289 penetrates through the second shutter 285 in the thickness direction, while being disposed correspondingly to the second through hole 287. Each of the third and fourth through holes 288 and 289 is formed in rectangular shape.

With the construction of the first and second shutters 284 and 285 disposed one above the other, the third through hole 288 is disposed correspondingly to the first through hole 286, and a first opening 282C is thereby formed. Simultaneously, the fourth through hole 289 is disposed correspondingly to the second through hole 287, and a second opening 283C is thereby formed.

The first and second shutters 284 and 285 are configured to be moved relatively to each other in the longitudinal direction, and thereby can completely open, and also, partially or completely close the first and second openings 282C and 283C on a similar basis.

Thus, the shield 239C according to the present modification has the first opening 282C and the second opening 283C. Hence, the shield 239C can achieve advantageous effects similar to those achieved in the second exemplary embodiment.

### 5. Third Exemplary Embodiment

### (5-1) Entire Construction

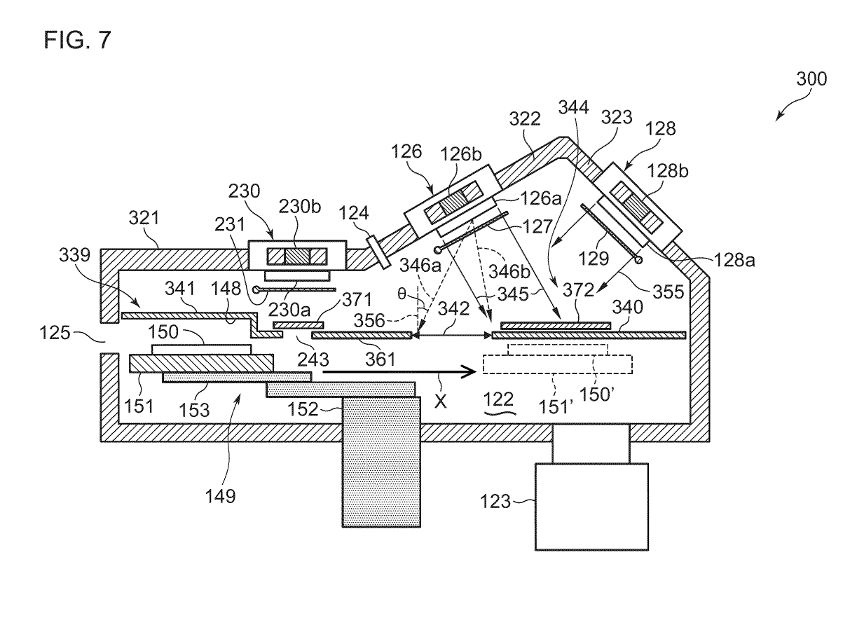

Next, with reference to FIG. 7, explanation will be made for a manufacturing apparatus according to a third exemplary embodiment. A manufacturing apparatus 300 according to the present exemplary embodiment is different from the manufacturing apparatus 200 of the second exemplary embodiment in that first and second targets are disposed while being obliquely tilted with respect to the surface of the substrate held by the holder mount. In the following description, explanation will be made for the changed construction, whereas explanation for components provided similarly to those in the second exemplary embodiment will be omitted. In the drawing, the same reference numerals are assigned to the same components as those used in the second exemplary embodiment.

As shown in the drawing, the manufacturing apparatus 300 according to the present exemplary embodiment includes the first cathode part 126, the second cathode part 128 and the third cathode part 230. In the first and second cathode parts 126 and 128, the first and second targets 126a and 128a are held while being obliquely tilted with respect to the surface of the substrate 150 held by the holder mount 151. It should be noted that the surface of the first target 126a is set to be tilted with respect to the substrate 150 at an angle of 20 to 70 degrees, and more preferably, at an angle of 30 to 60 degrees. In the third cathode part 230, the third target 230a is held roughly in parallel to the surface of the substrate 150 held by the holder mount 151.

The first target 126a is held while a normal 345 from the surface of the first target 126a is tilted with respect to a normal 356 from the surface of the substrate 150 held by the holder mount 151. The second target 128a is held while a normal 355 from the surface of the second target 128a is tilted with respect to the normal 356 from the surface of the substrate 150 held by the holder mount 151 in a direction intersecting with the normal 345 from the surface of the first target 126a.

In the present exemplary embodiment, the top surface of a vacuum chamber 321 is partially formed in a chevron shape. The first cathode part 126 is disposed on a side 322 that is one of the opposed sides of the chevron-shaped portion, whereas the second cathode part 128 is disposed on a side 323 that is the other of the opposed sides of the chevron-shaped portion.

The manufacturing apparatus 300 is provided with a shield 339. The shield 339 is disposed between the first, second and third cathode parts 126, 128 and 230 and the substrate 150. The shield 339 includes a first shield 340 and a second shield 341. A mask 361, formed by a plate-shaped member, is disposed in a region interposed between one side of the first shield 340 and that of the second shield 341, i.e., the opposed sides of the first and second shields 340 and 341.

An opening 342 is formed in a region interposed between the opposed sides of the mask 361 and the first shield 340. The third opening 243 is formed in a region interposed between the opposed sides of the mask 361 and the second shield 341.

The first shield 340 is disposed for shielding a region of the substrate 150 held by the holder mount 151, i.e., a region to which an erosion region of the first target 126a is projected along the normal 345 from the surface of the first target 126a. More specifically, the first shield 340 shields the region enclosed by normal lines from the outer edge of the erosion region of the first target 126a regardless of the location of erosion caused on the first target 126a. In the present exemplary embodiment, the first target 126a is held while the normal 345 from the surface of the first target 126a is tilted with respect to the normal 356 from the surface of the substrate 150 held by the holder mount 151. Hence, the first shield 340 is disposed in a position displaced rightward in the drawing by that much from the position immediately below the first target 126a.

The mask 361 is disposed for shielding a region that an angle formed by an incidence direction 346a of each of the sputtered particles produced from the center of the first target 126a and the normal 356 from the surface of the substrate 150 held by the holder mount 151, i.e., the incidence angle θ is greater than 45 degrees. Thus, the mask 361 shields most of such sputtered particles with the incidence angle θ of greater than 45 degrees.

The shield 339 includes a shutter 344 for closing the opening 342 and the third opening 243, respectively. The shutter 344 is composed of a first shutter 371 and a second shutter 372. The first shutter 371 is disposed so as to be capable of closing the third opening 243. The second shutter 372 is disposed so as to be capable of closing the opening 342. The first shutter 371 and the second shutter 372 are respectively disposed so as to be moved on and in parallel to the mask 361 and the first shield 340 along the feeding path. The first shutter 371 and the second shutter 372 are configured to adjust the feeding-path directional width of the third opening 243 and that of the opening 342, respectively. In other words, the first shutter 371 and the second shutter 372 can completely open, and also, partially or completely close the third opening 243 and the opening 342, respectively.

### (5-2) Actions and Effects

Next, explanation will be made for actions and effects of the manufacturing apparatus 300 with the aforementioned construction. To form the tunnel barrier layer 15 on the magnetic reference layer 14, the substrate 150 (FIG. 2) with the magnetic reference layer 14 formed thereon is carried onto the holder mount 151 through the substrate installation port 125 shown in FIG. 7.

The manufacturing apparatus 300 is configured to perform sputtering of a getter material by applying high frequency power to the second target 128a, while the first shutter 371, the second shutter 372, the first target shutter 127 and the third target shutter 231 are closed whereas the second target shutter 129 is opened.

Next, the manufacturing apparatus 300 is configured to perform sputtering by applying high frequency power to the third target 230a, while the second target shutter 129 is closed whereas the third target shutter 231 and the first shutter 371 are opened. Simultaneously, the substrate holding part 149 is configured to linearly move the substrate 150. The substrate 150 is thereby caused to pass immediately below the third opening 243.

Sputtered particles, produced from the surface of the third target 230a through the sputtering, pass through the third opening 243 and deposit on the surface of the substrate 150. Thus, in the manufacturing apparatus 300, an Mg film is formed on the surface of the substrate 150.

Next, the manufacturing apparatus 300 is configured to perform sputtering by applying high frequency power to the first target 126a, while the third target shutter 231 and the first shutter 371 are closed whereas the first target shutter 127 and the second shutter 372 are opened. Simultaneously, the substrate holding part 149 is configured to linearly move the substrate 150. The substrate 150 is thereby caused to pass immediately below the opening 342.

Sputtered particles, produced from the surface of the first target 126a through the sputtering, pass through the opening 342 and deposit on the surface of the substrate 150. Thus, the manufacturing apparatus 300 forms an MgO film on the Mg film that has been already formed on the surface of the substrate 150. With use of the third target 230a, an Mg film may be further formed on the tunnel barrier layer 15 made of MgO.

The manufacturing apparatus 300 with the aforementioned construction is configured to shield the region of the substrate 150 held by the holder mount 151, i.e., the region to which an erosion region of the first target 126a is projected along the normal 345 from the surface of the first target 126a, and the region that the incidence angle θ of each of the sputtered particles produced from the center of the first target 126a is greater than 45 degrees. Therefore, the manufacturing apparatus 300 can achieve advantageous effects similar to those achieved in the first exemplary embodiment.

In the present exemplary embodiment, the first target 126a is held while the normal 345 from the surface of the first target 126a is tilted with respect to the normal 356 from the surface of the substrate 150 held by the holder mount 151. Therefore, the manufacturing apparatus 300 can inhibit the substrate 150 from being damaged by oxygen ions, and simultaneously, can deposit the sputtered particles, which are produced from the first target 126a and have roughly perpendicular incidence angles, on the substrate 150. Moreover, the manufacturing apparatus 300 can achieve advantageous effects similar to those achieved by the manufacturing apparatus 200 of the second exemplary embodiment, because sputtered particles with the incidence angle θ defined as positive and those with the incidence angle θ defined as negative can pass through the opening 342.

In the manufacturing apparatus 300 according to the present exemplary embodiment, sputtered particles with the incidence angle θ defined as positive and those with the incidence angle θ defined as negative are caused to pass through the single opening 342. Hence, necessity of a second opening can be eliminated, and the manufacturing apparatus 300 can be entirely formed with a small size.

In the present exemplary embodiment, the tunnel barrier layer 15 made of MgO is configured to be formed on the Mg film. Hence, the present exemplary embodiment can achieve advantageous effects similar to those achieved in the second exemplary embodiment.

### 6. Modifications

The present invention is not limited to the aforementioned exemplary embodiments, and a variety of changes can be arbitrarily made without departing from the scope of the present invention.

In the aforementioned exemplary embodiments, explanation has been made for the tunnel barrier layer 15 of an MTJ device to be used as a reading part of an HDD. However, the present invention is also applicable to a tunnel barrier layer of an MTJ device to be used as an MRAM.

In the aforementioned exemplary embodiments, the first target made of magnesium oxide has been explained as a specific example of the first target. However, in the present invention, the first target is not limited to the above, and may be made of zinc oxide or a gate insulator film containing oxide (hafnium oxide) to be used as a high dielectric constant target insulator film or the like. The gate insulator film is herein also an extremely thin oxide film with a film thickness of 5 nm or less, and more preferably, a film thickness of 3 nm or less.

In the aforementioned exemplary embodiments, the first target made of magnesium oxide has been explained as a specific example of the first target. However, the present invention is also applicable to an example that reactive sputtering is configured to be performed using a metal target such as magnesium (Mg) while oxygen is introduced through a gas inlet disposed in the vicinity of the substrate. When sputtering is performed for the magnesium target while oxygen is introduced into the chamber, the surface of the magnesium target is oxidized, and as described above, oxygen negative ions are produced. This causes a problem of damage on a deposited film To cope with the problem, either the tunnel barrier layer 15 or the gate insulator film with better film quality can be formed by shielding the oxygen negative ions using the shutter of the present invention. In this case, DC power is required to be applied to the metal target.

The aforementioned exemplary embodiments have explained the examples that the manufacturing apparatus is configured to form the reading part of the magnetic head of the HDD. However, the present invention is not limited to the configuration, and is also applicable to examples of film deposition of a variety of magnetic devices.

The aforementioned exemplary embodiments have explained the examples that the substrate holding part includes the robot configured to linearly move the substrate. However, in the present invention, the construction of the substrate holding part is not limited to the above. For example, the substrate holding part may include a rail and a carriage configured to run on the rail, and further, a holder base may be connected onto the carriage.

What is claimed is:

1. A method of manufacturing a tunnel barrier layer or a gate insulator film, the method being configured to form the tunnel barrier layer or the gate insulator film on a surface of a substrate by means of sputtering of a target, wherein
a shield is configured to shield a region of the substrate to which an erosion region of the target is projected along a normal from a surface of the target and sputtered particles are configured to deposit on the substrate linearly moved when the sputtered particles pass through an opening formed in the shield.

2. The method of manufacturing a tunnel barrier layer or a gate insulator film according to claim 1, wherein the shield is configured to shield a region that an incidence angle formed by a normal from the surface of the substrate and an incidence direction of each of sputtered particles produced from a center of the target is greater than 45 degrees.

3. The method of manufacturing a tunnel barrier layer or a gate insulator film according to claim 1, wherein the tunnel barrier layer or the gate insulator film has a film thickness of 5 nm or less.

4. The method of manufacturing a tunnel barrier layer or a gate insulator film according to claim 1, wherein the tunnel barrier layer or the gate insulator film is formed by causing the sputtered particles to deposit on the surface of the substrate when the incidence angle of each of the sputtered particles is positive with respect to the normal from the surface of the substrate and when the incidence angle of each of the sputtered particles is negative with respect to the normal from the surface of the substrate.

5. The method of manufacturing a tunnel barrier layer or a gate insulator film according to claim 4, wherein
the substrate is configured to be moved roughly in parallel to the surface of the target,
the sputtered particles are configured to deposit on the substrate when the sputtered particles have the positive incidence angle and pass through a first opening formed in the shield, and
the sputtered particles are configured to deposit on the substrate when the sputtered particles have the negative incidence angle and pass through a second opening formed in the shield and separated away from the first opening.

6. An apparatus for manufacturing a tunnel barrier layer or a gate insulator film, the apparatus being configured to form the tunnel barrier layer or the gate insulator film on a surface of a substrate by means of sputtering of a target, the apparatus comprising:
a shield being configured to shield a region of the substrate to which an erosion region of the target is projected along a normal from a surface of the target and further shield a region that an incidence angle formed by an incidence direction of each of sputtered particles produced from a center of the target and a normal from the surface of the substrate is greater than 45 degrees; and
a substrate holding part being configured to linearly move the substrate along a feeding path, and wherein
the sputtered particles are configured to deposit on the surface of the substrate when the sputtered particles pass through an opening formed in the shield.

7. The apparatus for manufacturing a tunnel barrier layer or a gate insulator film according to claim 6, wherein
the shield has a first opening and a second opening formed in a position away from the first opening,
the sputtered particles are configured to deposit on the substrate configured to be linearly moved when the sputtered particles have the incidence angle defined as positive with respect to the normal from the surface of the substrate and pass through the first opening, and
the sputtered particles are configured to deposit on the substrate configured to be linearly moved when the sputtered particles have the incidence angle defined as negative with respect to the normal from the surface of the substrate and pass through the second opening.

8. The apparatus for manufacturing either a tunnel barrier layer or a gate insulator film according to claim 6, further comprising:
a shutter being configured to adjust a feeding-path directional width of the opening.

9. The apparatus for manufacturing a tunnel barrier layer or a gate insulator film according to claim 7, wherein
the shield has a first shutter and a second shutter disposed above the first shutter,
the first shutter has a first through hole and a second through hole,
the second shutter has a third through hole and a fourth through hole, the third through hole being disposed correspondingly to the first through hole, the fourth through hole being disposed correspondingly to the second through hole,
the first opening is formed by the first through hole and the third through hole,
the second opening is formed by the second through hole and the fourth through hole, and
a feeding-path directional width of the first opening and a feeding-path directional width of the second opening are configured to be adjusted by moving the first shutter and the second shutter relatively to each other.
